(19) United States
(12) Patent Application Publication
(10) Pub. No.: US 2005/0201457 A1
(43) Pub. Date: Sep. 15, 2005

(54) Distributed arithmetic adaptive filter and method

(76) Inventors: Daniel Jackson Allred, Douglasville, GA (US); David Verl Anderson, Alpharetta, GA (US); Walter Geeshan Huang, Greer, SC (US); Venkatesh Krishnan, Atlanta, GA (US); Heejong Yoo, San Diego, CA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/076,741

(22) Filed: Mar. 10, 2005

Related U.S. Application Data
(60) Provisional application No. 60/552,103, filed on Mar. 10, 2004.

(51) Int. Cl. H03K 5/159

(52) U.S. Cl. 375/232

(57) ABSTRACT

Systems and methods for very high throughput adaptive filtering using distributed arithmetic are disclosed. One distributed arithmetic adaptive filter may include a memory for storing a first and second lookup table. The first lookup table may include 2^{K} filter weights addressed by the rightmost bits of each of K signal samples stored in a plurality of registers. The filter may include a controller configured to update the second lookup table with each possible combination of the sums of the K most recent input samples and update each of the 2^{K} filter weights of the first lookup table based on the combination of the sums of the K most recent input samples stored in the second lookup table. The second lookup-table may be updated during a filtering operation that uses the first lookup-table. One filter may include a plurality of sub-filters with each sub-filter having first and second lookup tables.

### CROSS-REFERENCE TO RELATED APPLICATIONS

This application claims priority to and benefit of U.S. Provisional Patent Application entitled, “Distributed Arithmetic Adaptive Filter,” assigned Ser. No. 60/552,103, and filed on Mar. 10, 2004, which is incorporated by reference in its entirety.

### TECHINICAL FIELD

This invention relates generally to digital signal processing, and more particularly, to systems and methods for adaptive digital filtering of signals using a distributed arithmetic adaptive filter.

### BACKGROUND

Many digital signal processing (DSP) applications use linear filters that can adapt to changes in the signals they process. Adaptive filters find extensive use in several DSP applications including acoustic echo cancellation, signal de-noising, sonar signal processing, clutter rejection in radars, and channel equalization for communications and networking systems.

In many cases the sampling frequencies for digital processing of these signals are close to the system clock frequencies. Thus, it is important for the adaptive filters implemented to have a high throughput. For systems with requirements of low power consumption, a high throughput can make it possible to lower the system clock rate, resulting in lower power.

The hardware implementation of adaptive filters may use one or more DSP microprocessors or a custom logic design using one or more hardware multiply-accumulate (MAC) units. While an implementation using DSP microprocessors provides easy programmability, a serial implementation on a single DSP microprocessor adversely affects throughput. This throughput degradation can be especially true for higher order filters. Custom logic design using one or more hardware MAC units may be used to parallelize the implementation and thus improve the throughput, but at the cost of increased logic complexity, chip area usage, and power consumption.

Methods have been developed for the parallel implementation of static digital filters in field programmable gate arrays (FPGAs) or custom ICs. For example, Distributed Arithmetic (DA) may be one method used. Generally speaking, the DA approach reads the contents of memory to perform the weighted sum operation in b cycles, where b is the number of bits of precision of the input. One actual circuit implementation of this concept, for example, is provided in U.S. Pat. No. 4,450,533, granted on May 22, 1984 to J. P. Petit, et al., and entitled “Distributed Arithmetic Digital Processing Circuit,” which is incorporated by reference herein.

DA may be particularly advantageous because of the elimination of the need for hardware multipliers. Additionally, DA implementations are capable of implementing large filters with very high throughput. Also, DA filter implementations may achieve these advantages while retaining full precision, unlike filters using reduced sums and differences of powers of two. Finally, the filter coefficients used in DA filter implementations may be stored in memory, rather than in the hardware configuration as with canonical signed digit (CSD) filters.

Although DA filtering has many potential advantages, a problem presents itself when using DA for adaptive filtering. That is, the efficiency gains achieved through the DA implementation may be almost entirely eliminated when the coefficients are updated with every sample. Thus, past attempts to implement adaptive filters using DA may not be suitable for many practical applications.

Accordingly, what is needed is a system and method for implementing DA-based adaptive filters (DAAF) that retains the throughput advantages of DA non-adaptive filters.

### SUMMARY

Systems and methods for adaptive filtering using distributed arithmetic are described.

One embodiment of system for adaptive filtering comprises a distributed arithmetic adaptive filter including a plurality of registers, each register storing one of K incoming signal samples. The filter further includes a memory element for storing a first and second lookup table, the first lookup table including 2^{K} filter weight sums. Each of the 2^{K} filter weight sums are addressed by at least one bit of each of the K signal samples stored in the plurality of registers. The filter further includes a controller configured to: update the second lookup table with each possible combination of the sums of the K most recent input samples; and update each of the 2^{K} filter weight sums of the first lookup table based on the combination of the sums of the K most recent input samples stored in the second lookup table.

One embodiment of a method for adaptive filtering includes filtering a signal with at least one of a plurality of filter weight sums stored in a first lookup table, each of the filter weight sums addressed by at least one bit of each of a plurality of received input samples. The method further includes updating content in a second lookup table during the step of filtering the signal, the second look-up table contents including sums of the plurality of input samples.

Another embodiment of a digital adaptive filter includes at least one register for storing K input samples, and at least one sub-filter. Each sub-filter accesses a first and second lookup table, the first lookup table includes a plurality of filter weight sums. The plurality of filter weight sums are addressed by at least one bit of each of the signal samples stored in the at least one register. The second lookup table includes a plurality of values dynamically updated based on the sums of the K input samples.

Another exemplary method for adaptive filtering includes filtering a signal with a plurality of sub-filters, each sub-filter accessing a first and second lookup table. The first lookup table includes a plurality of filter weight sums, and the plurality of filter weight sums are addressed by at least one bit of each of the signal samples stored in the at least one register. The second lookup table includes a plurality of values dynamically updated based on the sums of K input samples.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a block diagram of one embodiment of a distributed arithmetic (DA) adaptive filter.

FIG. 2 depicts a block diagram of an embodiment of a distributed arithmetic filter module which may be used within the distributed arithmetic (DA) adaptive filter of FIG. 1, using a single filtering lookup table.

FIG. 3 depicts block diagram of another embodiment of a distributed arithmetic filter module which may be used within the distributed arithmetic (DA) adaptive filter of FIG. 1, using a plurality of base filtering lookup tables.

FIG. 4 depicts an exemplary flowchart for the filtering each sample received by the distributed arithmetic adaptive filter of FIG. 1.

FIG. 5 depicts an update of the contents of the auxiliary lookup table of FIG. 1, as performed by the auxiliary lookup table update step of FIG. 4.

FIG. 6 depicts a block diagram of an exemplary address rotation circuit which may be implemented within an address controller of the distributed arithmetic adaptive filter of FIG. 1.

FIG. 7 depicts a block diagram of another embodiment of a distributed arithmetic adaptive filter optimized for large filter sizes by using a plurality of base filter and adaptation units.

FIG. 8 depicts a block diagram an embodiment of an exemplary base filter and adaptation unit of FIG. 7.

### DETAILED DESCRIPTION

Systems and methods for adaptive filtering based on distributed arithmetic (DA) are described. Compared to a multiplier-based architecture, the performance of the disclosed systems may demonstrate increased throughput for comparable power consumption. The systems and methods retain the potential throughput advantages of DA non-adaptive filters. Further, the throughput may be nearly independent of the filter size, and largely depends on the bit precision of the input signal. Because the power consumption of digital circuits is approximately linearly related to clock speed, the throughput improvement can also be translated to a power-consumption improvement by decreasing the clock speed of the DA-adaptive filter. For example, a DSP chip with a single MAC operation may be clocked at near 300 MHz to implement a 1024-tap adaptive filter at a 44.1 kHz sample-rate, while the disclosed DA-adaptive filter systems and methods may be clocked at less than 2 MHz.

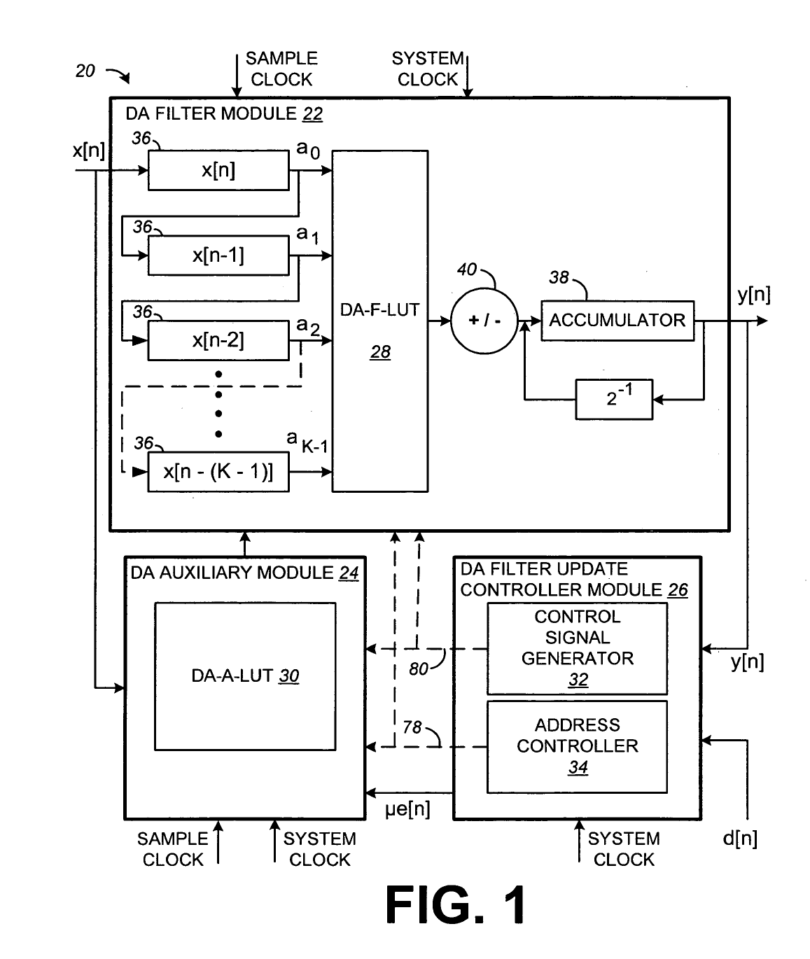

FIG. 1 depicts an exemplary block diagram of an embodiment of a DA-Adaptive Filter (DAAF) 20 implementing a Least Mean Square (LMS) adaptation algorithm in a Finite Impulse Response (FIR) filter. Although the LMS adaptation algorithm is chosen as an example, it should be understood that the systems and methods for adaptive filtering based on distributed arithmetic can be extended to other adaptation algorithms such as, but not limited to Normalized LMS, Variable Step-Size LMS, Linearly Constrained LMS, Transform Domain LMS, and all types of Signed LMS algorithms. In addition, although a FIR filter has been chosen as an exemplary filter, the disclosed systems and methods may be applied to Infinite Impulse Response (IIR) filters, or other types of filters, as well. DAAF 20 may be a digital apparatus or digital processing circuit which may be implemented in an FPGA, for example.

In general, DAAF 20 includes a DA Filter Module 22, a DA Auxiliary Module 24, and a DA Filter Update Controller Module 26. In general, DA Filter Module 22 filters incoming signal samples at time n (represented by input x[n]) using a DA Filter Lookup table (DA-F-LUT) 28 (rather than one or more MAC units). DA Auxiliary Module 24 and DA Filter Update Controller Module 26 collectively operate to update the contents of DA-F-LUT 28 to perform adaptive filtering on a sample-by-sample basis. These, and other features of the DAAF 20, will be described in more detail below.

It should be understood that a lookup table, in general, may be any data structure capable of addressing content elements (e.g. data) stored therein. The addresses for the lookup table may be synonymous with the location in the lookup-table (i.e. implicit), or may be such that the location in the lookup-table is explicitly supplied. The content elements, which may also be referred to herein as DATA or value entries, stored within a lookup-table (e.g. DA-F-LUT 28) may be stored in a memory element, such as (but not limited to) random access memory (RAM), a read-only memory (ROM), or an erasable programmable read-only memory (EPROM, EEPROM, or Flash memory).

DA Filter Module 22 may be a DA Finite Impulse Response (FIR) filter. A discrete-time linear finite impulse response filter generates the output y[n] as a sum of delayed and scaled input samples x[n], which may be represented as:

$$y [ n ] = {\sum }_{i = 0}^{K - 1} {w}_{i} x [ n - i ] \qquad ( Eq . 1 )$$

where K is the number of delayed input samples x, and w represents the tap weights of the FIR filter.

A typical digital implementation using MAC units may require K MAC operations. A single processing unit digital signal processor completes this operation in O(K) clock cycles given a single instruction for each MAC plus data fetch, address generation, and loop control. Thus, the system clock of an implementation using a digital signal processor should operate at a clock speed of at least K times faster than the rate at which the signal is sampled, and often as much as 5K times faster. For systems in which the maximum system clock speed is limited by power consumption limitations or other constraints, the throughput of the FIR filter, defined as the number of signal samples processed per second may be similarly limited. This limitation may become severe for large filter sizes (large K). Although employing multiple processing units improves the throughput, the corresponding increase in logic complexity, on-chip area and power consumption may render such implementations unattractive.

However, instead of the described digital signal processor implementation, MAC operations in a filter may be replaced by a series of lookup table (LUT) accesses and summations as is performed by DA Filter Module 22. DA Filter Module 22 implements the filtering operation of Eq. 1 in a bit-serial fashion known as distributed arithmetic (DA). DA can achieve higher throughput (faster computation) and lower logic complexity at the cost of increased memory usage (e.g. for the storage for the associated LUT). The DA implementation allows the filtering operation to be performed in a fixed number of clock cycles depending on the bit precision (i.e. the number of bits, represented by B) of the signal samples, regardless of the filter size. Thus, the DA architecture enables a high throughput implementation for large FIR filters. Although DA implementations may result in increased use of memory to store the filter weights in the lookup table, advances in memory technology has resulted in shrinking memory sizes and costs, thus rendering the DA implementation of digital filters an attractive option.

DA is a bit-serial operation that implements a series of fixed-point MAC operations (equivalently, an inner product of two vectors) in a fixed number of steps, regardless of the number of terms to be calculated. The conversion of the MAC operations into a bit-serial operation may be achieved as follows. First, the signal samples (x[n]) to the filter may be represented as B-bit 2's complement binary numbers with the radix point to the immediate right of the sign-bit,

$$x [ n - i ] = - {b}_{i0} + {\sum }_{l = 1}^{B - 1} {b}_{il} {2}^{- l} , i = 0 , … K - 1 \qquad ( Eq . 2 )$$

where bᵢₗ is the lth bit in the 2's complement representation of x[n−i]. Then, inserting Eq. 2 into Eq. 1, and swapping the order of the summations yields:

$$y [ n ] = - [ {\sum }_{i = 0}^{K - 1} {b}_{i0} {w}_{k} ] + {\sum }_{l = 1}^{B - 1} [ {\sum }_{i = 0}^{K - 1} {b}_{il} {w}_{i} ] {2}^{- l} \qquad ( Eq . 3 )$$

Thus, for a given set of wᵢ (i=0, . . . , K-1), the terms in the square braces may take only one of 2^{K} possible values, and these values may be stored in a filtering LUT. Specifically, in the embodiment of FIG. 1, this LUT is represented by DA-F-LUT 28.

The entry in DA-F-LUT 28 addressed by r, is given by

$$DA \text{-} F \text{-} {LUT}_{( r )} = {\sum }_{i = 0}^{K - 1} {c}_{i}^{( r )} {w}_{i} , r = 0 , … , {2}^{K} - 1 \qquad ( Eq . 4 )$$

where cᵢ^{(r)} is the i^{th} bit in the K-bit representation of the address r. In other words,

$$r = {\sum }_{i = 0}^{K - 1} {c}_{i}^{( r )} {2}^{i} \qquad ( Eq . 5 )$$

For each l, l=0, . . . , B-1, the term in the square braces in Eq. 3 is essentially the entry in the DA-F-LUT 28 with the address

$${\sum }_{i = 0}^{K - 1} {b}_{il} {2}^{i} .$$

In addition to look-up table DA-F-LUT 28, DA Filter Module 22 may include a bank of K shift registers 36 for storing the received K signal samples, and a sign bit control module 40 and an accumulator 38 for generating output signal y[n] based on Eq. 3.

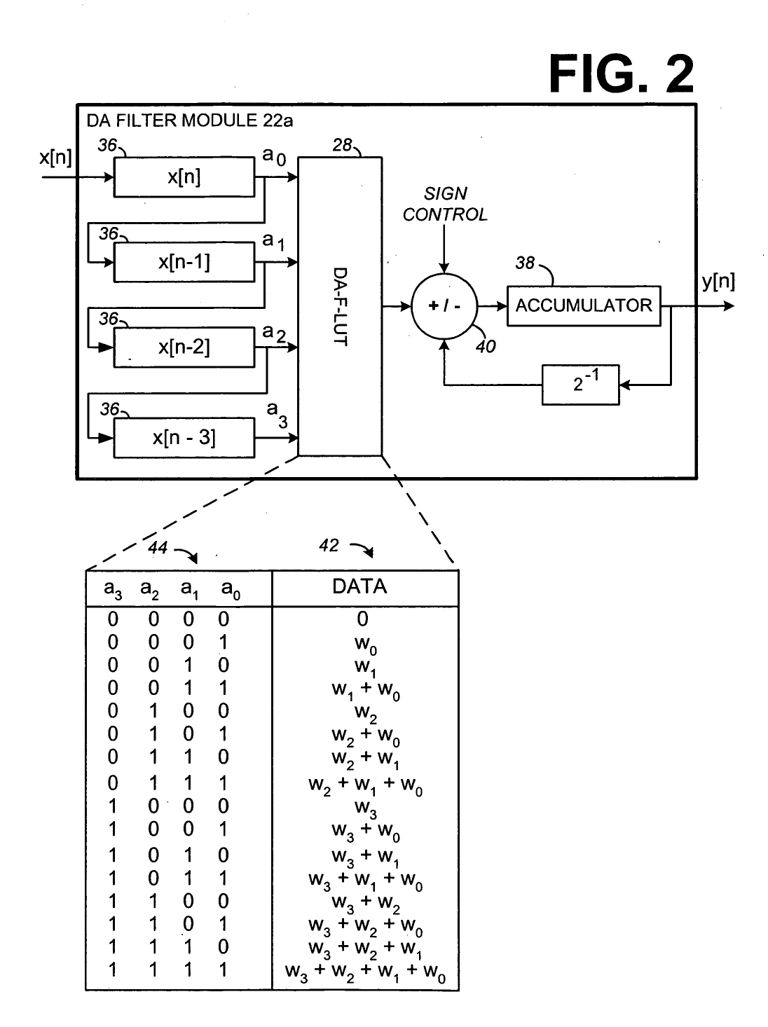

FIG. 2 depicts an exemplary DA Filter Module 22a, which may be used within DAAF 20 of FIG. 1. Although DA Filter Module 22 may include any number of taps, exemplary DA Filter Module 22a comprises 4-taps (K=4). Thus, the bank of shift registers 36 stores the four most recent consecutive input signal samples (x[n−i]; i=0, . . . ,3). The DATA 42 (e.g. the data values) stored in DA-F-LUT 28 is addressed by addresses 44, as is depicted in the inset corresponding to DA-F-LUT 28.

Specifically, the DATA of DA-F-LUT 28 includes all 16 possible combination sums of the filter weights w0, w1, w2, and w3. The concatenation of corresponding consecutive bits (here, the rightmost bits) of the shift registers becomes the address 44 (a₀, a₁, a₂, and a₃) for the corresponding DATA 42 in DA-F-LUT 28. The contents of each shift register 36 are shifted right at each clock cycle, and the corresponding DA-F-LUT 28 entries are also shifted and accumulated by accumulator 38 B consecutive times to generate the output y[n]. The sign bit control 40 changes the addition to subtraction for the sign bits which are included in the first expression in square brackets in Eq. 3.

The DA filtering operation performed by DA Filter Module 22 is completed in B steps, regardless of the number of taps, K. Although a significant gain in throughput may not be obtained when implementing small filter sizes, using the DA implementation for large filter sizes (K>>B) may result in substantial improvements in the throughput. However, regardless of filter size, cost, power, and speed savings may be achieved by not using a hardware multiplier.

Although DA Filter Module 22a (FIG. 2) is depicted as having 4-taps for the purposes of simplicity, it should be understood that any number of taps may be implemented by a corresponding change in the number of shift registers (for holding more input samples) and a respective change in the contents of DA-F-LUT 28 to hold each of the possible sums of the possible filter weights. However, as the filter size increases, the memory requirements of the DA-F-LUT 28 grow exponentially. For example, just as the depicted 4-tap DA Filter Module 22a uses 2⁴ entries (16 entries) in the DA-F-LUT 28, a 128-tap DA Filter Module would use 2¹²⁸ entries in the respective DA-F-LUT, which may require excessive memory for a particular application.

However, this potential problem may be alleviated by breaking up the filter into smaller base DA filtering units having LUTs with tractable memory sizes, and then summing the outputs of these units. For example, the summation in the square braces in Eq. 3 may be split so that a K tap filter is divided into m units of k tap DA base units (K=m×k). Thus, Eq. 3 can be written as

$$y [ n ] = ( {\sum }_{j = 0}^{m - 1} [ {\sum }_{i = jk}^{( j + 1 ) k - 1} {b}_{i0} {w}_{i} ] ) + {\sum }_{l = 1}^{B - 1} ( {\sum }_{j = 0}^{m - 1} [ {\sum }_{i = jk}^{( j + 1 ) k - 1} {b}_{il} {w}_{i} ] ) {2}^{- l} \qquad ( Eq . 6 )$$

where the terms in parenthesis in Eq. 6 may be implemented using m base units, each implementing the expression in square brackets.

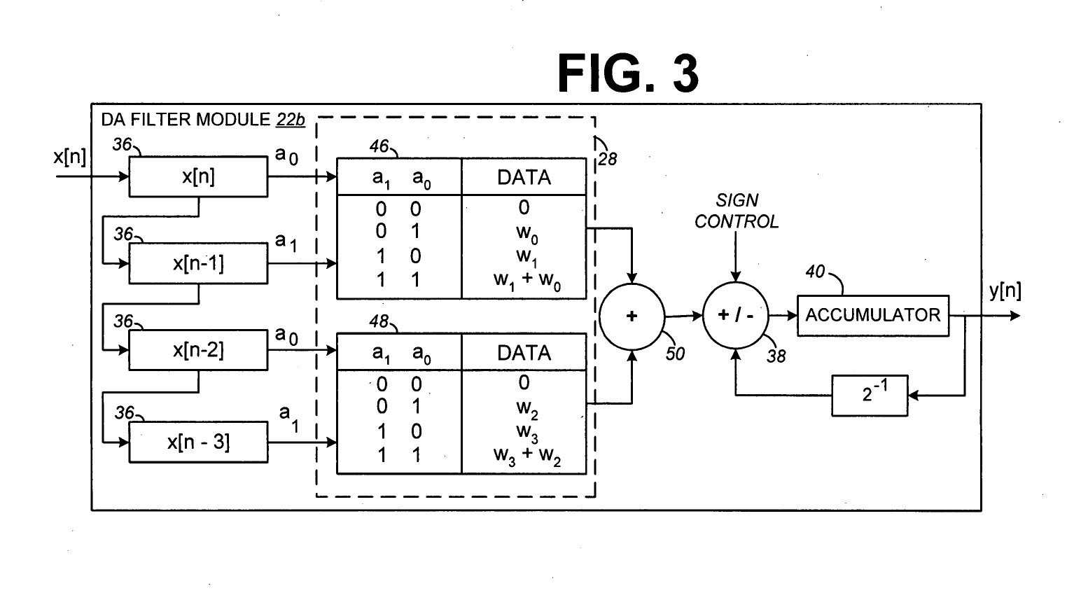

FIG. 3 depicts an embodiment of an exemplary DA Filter Module 22b circuit based on Eq. 6. The 4-tap DA Filter Module 22b breaks the equivalent DA-F-LUT 28 of DA Filter Module 22a (FIG. 2) into multiple base DA-F-LUT units 46 and 48. The corresponding DATA addressed by a₀ and a₁ for each base DA-F-LUT units 46 and 48 is summed by adder tree 50, resulting in the same output as the single DA-F-LUT 28 of FIG. 2, and thus, the remainder of the circuit remains the same as described in relation to DA Filter Module 22a.

The total memory storage requirements of base DA-F-LUT units 46 and 48 is less than the total memory storage requirements for the respective DATA contained in the DA-F-LUT 28 of DA Filter Module 22a. Specifically, the total memory requirement for an embodiment using multiple base LUTs is m×2^{k} memory elements. Thus, in the embodiment of FIG. 3, m=2 and k=2. Accordingly, unlike the DA-F-LUT 28 of DA Filter Module 22a (FIG. 2) which uses a total of 16 memory elements, base DA-F-LUT units 46 and 48 use a total of 2×2²=8 memory elements.

The total number of clock cycles required for an implementation using multiple, smaller base DA-F-LUTs is B+[log₂ (m)]. In comparison to the embodiment of FIG. 2, which completes filtering in B steps, the additional second term corresponds to the number of clock cycles required to implement adder tree 50 to calculate the total sum of the outputs of the multiple DA-F-LUT units (46 and 48 in FIG. 3). For the purpose of simplification, the clock cycle comparison assumes that each level of adders in the adder tree 50 takes the same amount of time to compute its output as it does to access the memory. However, in practice, the adder tree can take more or less time dependent on the specific design of adder tree 50.

Thus, in comparison to the embodiment of FIG. 2, the decrease in throughput of the embodiment of FIG. 3 is marginal. For instance, if K=128, then instead of 2¹²⁸ memory elements in a single DA-F-LUT implementation (e.g. FIG. 2), the filter can be broken into smaller base DA-F-LUT units such that k=4 and m=32, resulting in only 512 memory elements. In addition, the clock cycle requirement for a filter using k=4 and m=32 increases only marginally to 21 clock cycles, as compared with the single DA-F-LUT embodiment of DA Filter Module 22a (FIG. 2) that requires 16 clock cycles.

Now that a number of potential implementations of DA Filter Module 22 have been described, the adaptive filtering function of DAAF 20 is now described in more detail. Unlike a non-adaptive filter (which has static filter coefficients, and thus an unchanging DA-F-LUT), an adaptive filter updates the filter coefficients to adapt the filter's performance to optimally suit the input signal. Thus, an adaptive filter uses feedback to update the values of the filter coefficients to refine the filtering operation. In general, the process of using feedback to refine the filter coefficient values involves the use of a cost function, which is a criterion for optimum performance of the filter. One of the choices for the cost function may be the expected value of the squared error ζ between the filter output y[n] and a desired (e.g. reference) signal d[n].
ζ=E{e²[n]}=E{(d[n]−y[n])²} (Eq. 7)
A widely used adaptive filter is an LMS adaptive filter, which estimates the expected value of the squared error as the instantaneous squared error. For each input sample, the filter weights wᵢ[n], i=0, . . . , K-1 (in the DA-F-LUT 28) are updated according to:
wᵢ[n+1]=wᵢ[n]+μe[n]×[n−i] (Eq. 8)
where μ is the step size (e.g. adaptation parameter) and e[n] is the error signal.

One implementation of an LMS adaptive filter on a hardware system with a single MAC unit uses K MAC operations to perform the filtering, and (additionally) K MAC operations to perform the weight adaptation as in Eq. 8. In another embodiment, multiple MAC units may be employed to parallelize the adaptive filter implementation. In a multiple MAC-based LMS adaptive filter (MMAF) system, the filtering and the weight adaptation may, for example, be performed using one or more custom hardware MAC units.

The implementation on the MMAF system may be similar to an implementation of an adaptive filter on a DSP microprocessor. That is, in many modern DSP microprocessors, up to four MAC units process the input samples simultaneously. The throughput of the MMAF system depends on the filter length and the number of MAC units. As the number of MAC units increases, higher throughput can be achieved. However, the number of logic elements and the power consumption increase as well.

In contrast to filters using. MAC based operations, to implement a LMS version of DAAF 20, the DATA entries in the DA-F-LUT 28 (which contains all possible combination sums of the filter weights) of the DA Filter Module 22 are recalculated and updated on a sample-by-sample basis. In one embodiment, each weight may be updated individually according to Eq. 8, and then the DATA entries of DA-F-LUT 28 are regenerated using the new weights. However, this “brute-force” approach can be computationally expensive and time consuming, causing significant reduction in the filter throughput.

However the DAAF 20 of FIG. 1 implements an approach using fewer clock cycles than the described “brute-force” approach. For example, DA Filter Module 22 may perform the filtering operation on the incoming data samples with the current values of the weights stored in DA-F-LUT 28 as previously described with respect to the embodiments FIGS. 2 or 3. However, in addition to the DA Filter Module 22, the proposed DAAF 20 includes DA Auxiliary Module 24 and DA Filter Update Controller Module 26 which collectively function to ultimately update DA-F-LUT 28 to implement the adaptive filtering feature.

Assuming that the r^{th} entry in the DA-F-LUT is given by Eq. 4, if each term in the summation of Eq. 4 is updated according to the LMS algorithm, then the r^{th} entry in DA-F-LUT 28 may be updated according to,

$${\sum }_{i = 0}^{K - 1} {c}_{i}^{( r )} {w}_{i} [ n + 1 ] = {\sum }_{i = 0}^{K - 1} {c}_{i}^{( r )} {w}_{i} [ n ] + μ e [ n ] {\sum }_{i = 0}^{K - 1} {c}_{i}^{( r )} x [ n - i ] . \qquad ( Eq . 9 )$$

Accordingly, DA Auxiliary Module 24 contains Auxiliary LUT (DA-A-LUT) 30 which stores all possible combination sums of the K most recent input samples. Therefore, the r^{th} entry of the DA-A-LUT 30 is the term

$${\sum }_{i = 0}^{K - 1} {c}_{i}^{( r )} x [ n - i ] of Eq . 9.$$

Thus, in the described embodiment, DA-A-LUT should contain a corresponding sum for each of the entries to be updated in DA-F-LUT. Thus, the table size and structure of the DA-A-LUT 30 may be identical to that of the DA-F-LUT 28.

In general, DA Filter Update Controller Module 26 generates address signals 78 and control signals 80 for updating DA-A-LUT 30 and subsequently, the DA-F-LUT 28 (e.g. via Control Signal Generator 32 and Address Controller 34). For example, Control Signal Generator 32 may generate control signals 80, such as, but not limited to write-enable signals for each of the DA-F-LUT 28 and DA-A-LUT 30, address select lines for the DA-F-LUTs (to choose between the bits of the shift register arid the address signals provided by the Address Controller 34), sign-bit control for the adder 40, and any other signals to ensure the DA-F-LUT 28 is updated correctly. Address Controller 34 may generate read and write address signals 78 for each of the DA-F-LUT 28 and DA-A-LUT 30 to be used during the update procedures. Control Signal Generator 32 and Address Controller 34 are synchronized together so that all required signals are generated and present at the appropriate times.

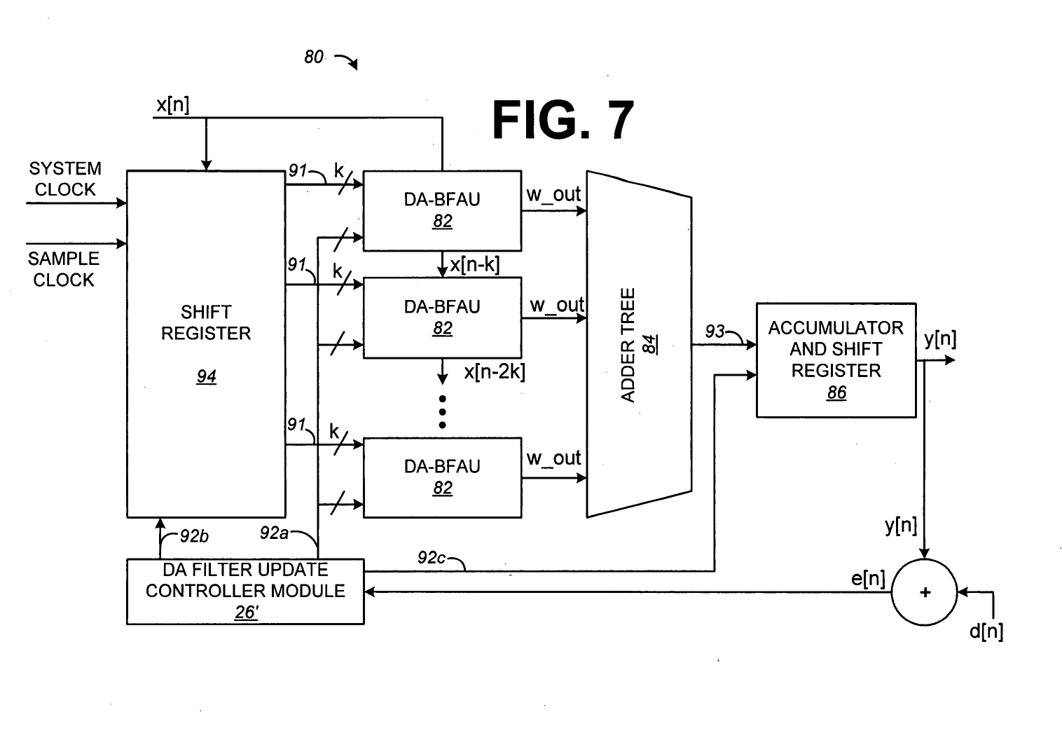

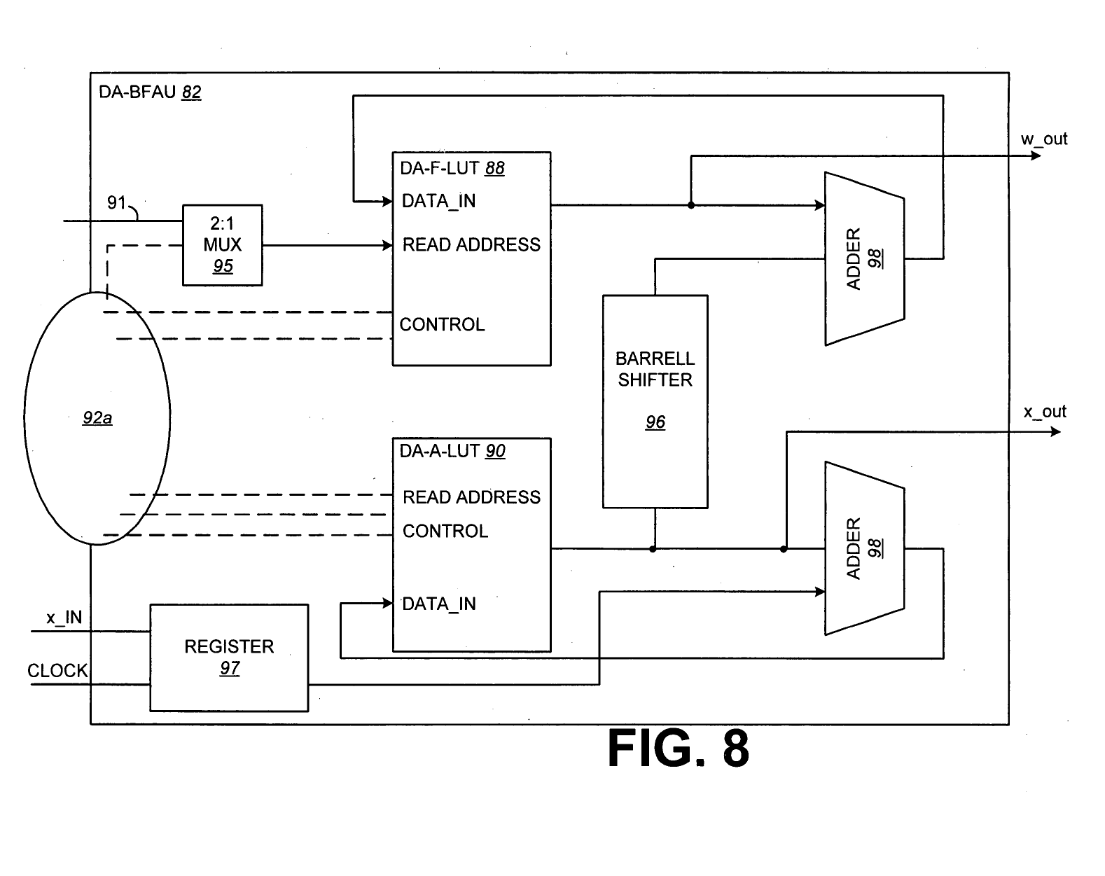

It should be understood that the non-adaptive embodiments of DA Filter Modules 22a and 22b depicted in FIG. 2 and FIG. 3, respectively, may require additional circuitry for the described adaptive embodiments. For example, adders and barrel shifters may be used to actually calculate the values to be stored within tables DA-F-LUT 28 and DA-A-LUT 30. For example, such circuitry is depicted with respect to the filter embodiments of FIGS. 7 and 8 (e.g. adders 96 and barrel shifter 98 of DA-BFAU 82), which will be described in more detail below.

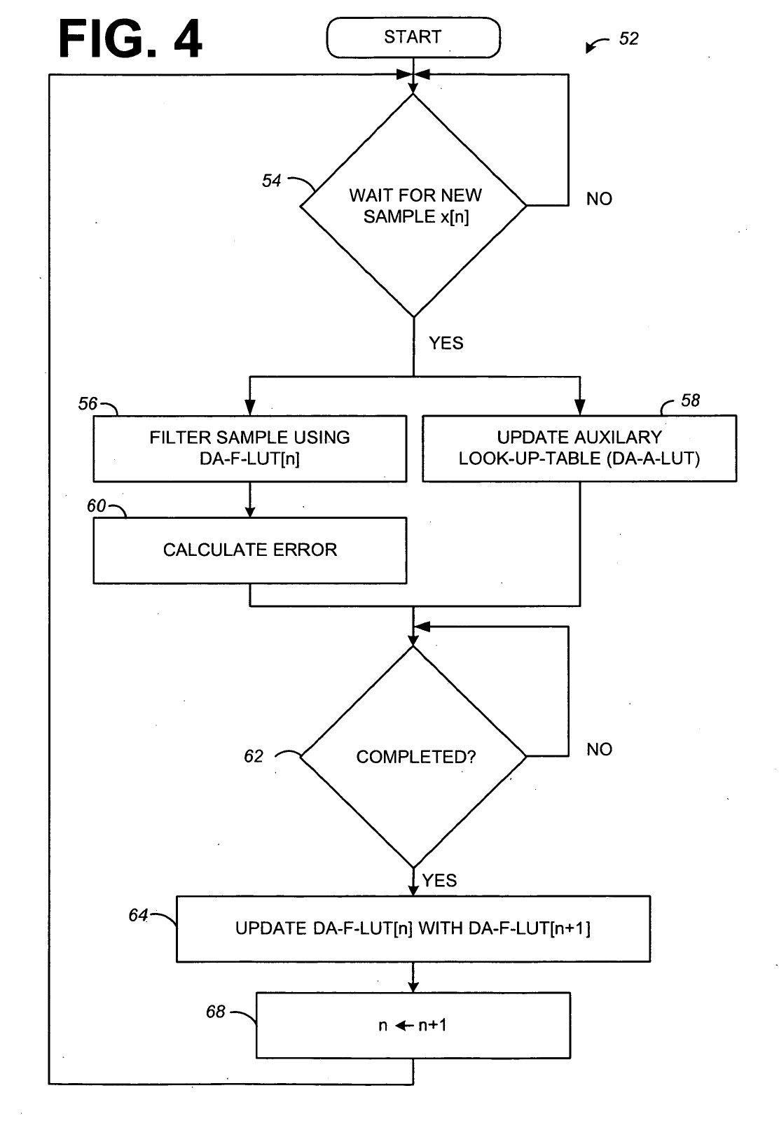

FIG. 4 depicts a flow diagram representing one embodiment of a filtering and adaptation routine 52 for a single sample x taken at time instance n. The flow filtering and adaptation routine 52 may, for example, be implemented by DAAF 20. The notations DA-A-LUT[n] and DA-F-LUT[n] are used to refer to the DATA values stored within DA-A-LUT 30 and DA-F-LUT 28, respectively, at the time instance n.

At decision 54, the routine waits for a new sample to be received (the “NO” condition) at DA Filter Module 22. Upon receiving a sample x[n] at DA Filter Module 22 (the “YES” condition), steps 56 (filtering) and 58 (updating the LUT) may both be commenced.

At step 56, samples x[n], x[n−1], . . . , x[n−K+1] are filtered by DA Filter Module 22 according to Eq. 3 and using DA-F-LUT[n]. At step 58, DA-A-LUT 30 may be updated from DA-A-LUT[n−1] to DA-A-LUT[n], such that DA-A-LUT 30 reflects all of the possible sums of the K most recent input samples (including sample x[n]). The updating of DA-A-LUT 30 may be performed in parallel with the filtering step 56. The DA Filter Update Controller Module 26 generates the addresses and control signals for updating the contents of the DA-A-LUT 30 and subsequently, the DA-F-LUT 28, as will be described in more detail below.

At step 60, the error, e[n] is calculated by DA Filter Update Controller Module 26. For example, for the LMS algorithm, the error may be obtained by calculating the difference between the desired and actual outputs (e.g. e[n]=d[n]−y[n]). The term μe(n) may then be quantized to the appropriate power of two.

Decision 62 may be triggered upon the completion of the filtering step 56, update step 58, and error calculation step 60 being completed. At step 64 the DA Filter Update Controller Module 26 provides addresses and control signals to access the contents of memory locations of DA-A-LUT 30 and DA-F-LUT 28. Using address and control signals from the DA Filter Update Controller 26, the DA Filter Module calculates the new filter coefficients, and these new filter coefficients are stored in the DA-F-LUT 28.

The new filter coefficient sums at time n+1 for each address location in the DA-F-LUT 28 are calculated by adding the current weight in that address (e.g. at time n) to the product of the step size (μ), error (e[n]), and the appropriate sum of the input samples in DA-A-LUT 30 (DA-A-LUT[n]) at the corresponding address. Thus, at step 64, the DA-F-LUT 28 is updated from DA-F-LUT[n] to DA-F-LUT[n+1], where DA-F-LUT[n+1] =DA-F-LUT[n]+μe[n] DA-A-LUT[n].

Once the DA-F-LUT is updated, the filtering and adaptation step at time n is complete. With respect to filtering and adaptation routine 52, for the purposes of brevity, the next sample received, x[n+1], may be represented as x[n] at step 68. Accordingly, the filtering and adaptation routine 52 may then be repeated with the next sample, x[n+1] (although represented as x[n] in each of the repeated steps).

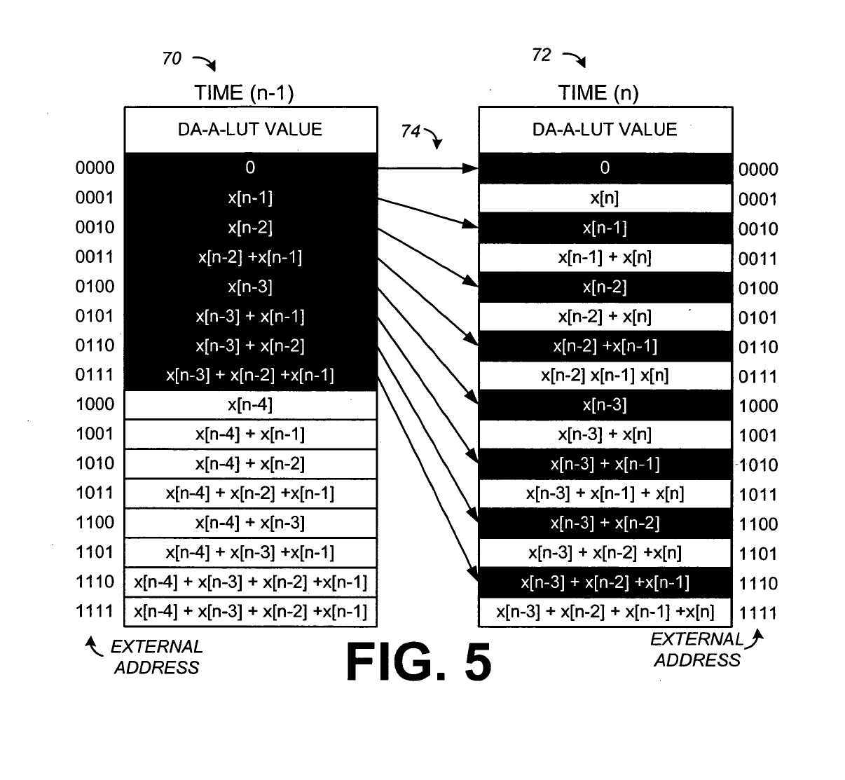

Now that a general overview of filtering and adaptation routine 52 has been described, the updates of the DA-A-LUT 30 at step 58, and DA-F-LUT 28 at step 64, are described in more detail. At step 58, the DATA contents in DA-A-LUT 30 is updated to DA-A-LUT[n] from DA-A-LUT[n−1]. FIG. 5 depicts a representation of an exemplary DATA update within DA-A-LUT 30. Specifically, for a filter having 4 taps (K=4), the contents of DA-A-LUT 30 at time n−1 is represented by DA-A-LUT[n−1] 70, and the updated DA-A-LUT 30 at time n is represented by DA-A-LUT[n] 72.

Looking still to FIG. 5, the contents of even addressed locations (i.e. locations with addresses having a 0 in the least-significant bit (LSB)) of the DA-A-LUT[n] 72 are the contents of the lower half (i.e. locations whose addresses have a 0 in the most-significant bit (MSB)) of the DA-A-LUT[n−1] 70). Additionally, the contents of the odd addressed locations (i.e. locations whose addresses have a 1 in the LSB) of the DA-A-LUT[n] 72 can be obtained from the even addressed locations of the DA-A-LUT[n] 72 according to:
DA-A-LUT₍₂ₗ₊₁₎[n]=DA-A-LUT₍₂ₗ₎[n]+x[n], l=0, . . . , 2^{k-1}−1 (Eq. 10)
Thus, the update of the DA-A-LUT[n] from DA-A-LUT[n−1] can be summarized by: (1) re-mapping the lower half of the DA-A-LUT[n−1] to even addressed locations of the DA-A-LUT[n] (as best depicted by the arrows 74); and (2) for each odd addressed location: reading the contents of the corresponding preceding even addressed location in DA-A-LUT[n] 72; adding the newest sample x[n] to the contents of the preceding even addressed location; and storing the value of the resulting sum back to the respective odd addressed location.

As to the re-mapping of the lower half of the DA-A-LUT[n−1], the contents could be physically moved to the new addresses in DA-A-LUT [n] 72 (e.g. instead of “re-mapping”). However, instead of physically moving the contents of the DA-A-LUT, this re-mapping operation can be performed by a left-rotation of the K address lines of the contents of DA-A-LUT 30. The address rotation allows the physical contents (e.g. the DATA) of the DA-A-LUT 30 to remain the same, although the logic external to DA-A-LUT 30 perceives the DATA as being remapped to the locations as shown in DA-A-LUT[n] 72 of FIG. 5.

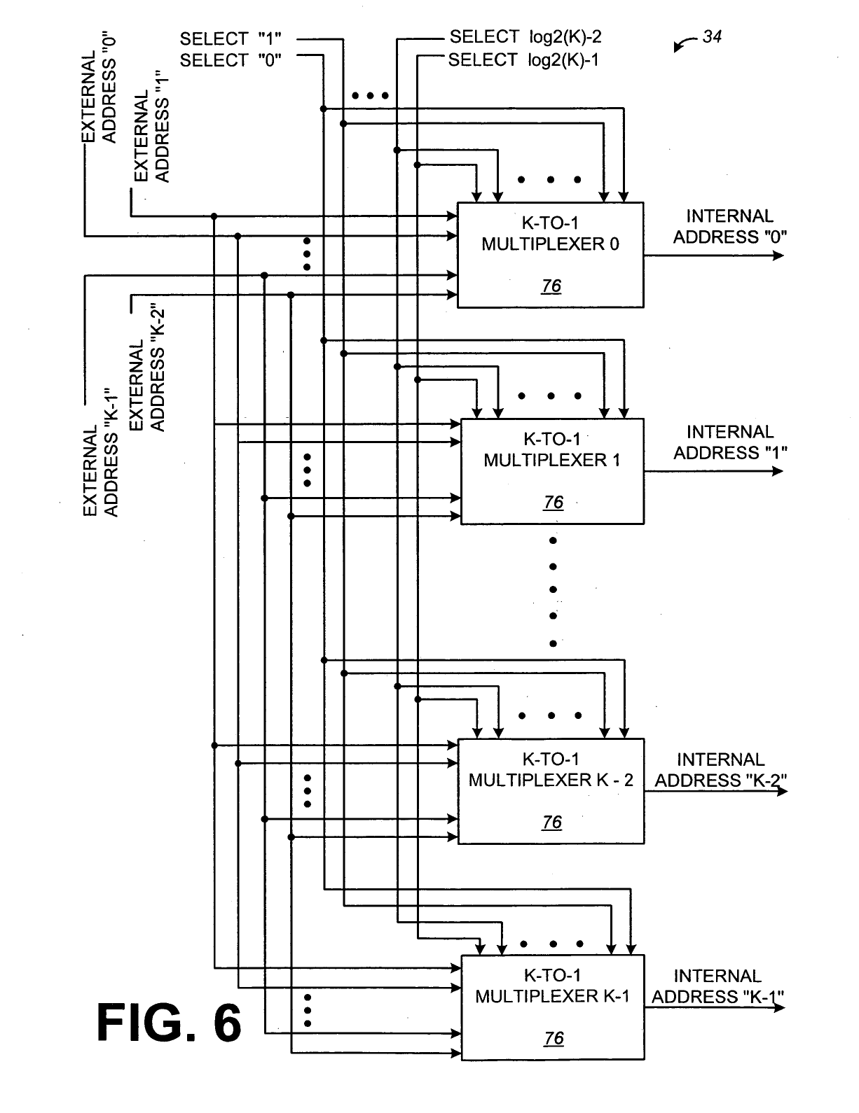

This address rotation can be achieved, for example, using address controller 34 of DA Filter Update Controller Module 26, and as depicted in more detail in FIG. 6. With respect to address controller 34, the term “internal address” refers to the physical addresses of the DA-A-LUT 30 (e.g. “internal” to the DA-A-LUT) and “external address” refers to the address at perceived by the external logic (e.g. by DA Filter Update Controller Module 26) through address lines 78 (FIG. 1). The relationship between the internal and the external addresses at times n−1 and n for K=4 (i.e. representing the rotation of address lines from time n−1 to time n) may be represented by the following table (which is also apparent from FIG. 5):

| | Time n − 1 | Time n |
|---|---|---|
| Internal | External | External |
| Address | Address | Address |
| 0000 | 0000 | 0000 |
| 0001 | 0001 | 0010 |
| 0010 | 0010 | 0100 |
| 0011 | 0011 | 0110 |
| 0100 | 0100 | 1000 |
| 0101 | 0101 | 1010 |
| 0110 | 0110 | 1100 |
| 0111 | 0111 | 1110 |
| 1001 | 1001 | 0011 |
| 1010 | 1010 | 0101 |
| 1011 | 1011 | 0111 |
| 1100 | 1100 | 1001 |
| 1101 | 1101 | 1011 |
| 1110 | 1110 | 1101 |
| 1111 | 1111 | 1111 |

Thus, the external address referring to a given internal address at the time n is the left-rotated version of the external address referring to the same internal address at the time n−1. Therefore, the effect of address rotation can be accomplished by connecting the external and the internal addresses via a K number of K-to-1 input multiplexers 76. The outputs of multiplexers 76 connect to the internal address lines of the DA-A-LUT 30. The select lines correspond to the bits of a counter, and this counter is incremented when a new sample arrives. Thus, the log2(K) select lines of each of the K multiplexers 76 are connected to the log2(K) bits of a counter, which is incremented with the sample clock (not depicted). Thus, by address rotation, the mapping of half the DA-A-LUT 30 can be done instantaneously at the arrival of the new sample x[n].

As mentioned above, the contents of the odd addressed locations of the DA-A-LUT[n] may be obtained by reading the contents of the corresponding preceding even addressed locations, adding the newest sample x[n], and then storing the result back into the respective odd addressed locations.

Now that the update of the DA-A-LUT 30 has been described, the update of the DA-F-LUT[n+1] as performed at step 64, is described in more detail. Specifically, from Eq. 9, the update from time n to n+1 of the r^{th} entry of the DA-F-LUT is given by,
DA-F-LUT₍ᵣ₎[n+1]=DA-F-LUT₍ᵣ₎[n]+μe[n]DA-A-LUT₍ᵣ₎[n]. (Eq. 11)

Thus, the DA-F-LUT[n+1] may be updated by reading the contents of the same memory address in both the DA-F-LUT[n] and DA-A-LUT[n], multiplying the contents of the address in DA-A-LUT[n] by μe[n], adding this quantity to the contents of the address in the DA-F-LUT[n], and finally storing the result back in the location of the same memory address of the DA-F-LUT[n+1]. This process may be repeated from address 1 to address 2^{K}−1 until all address locations DA-F-LUT[n+1] are updated with the new contents. The entry in address 0 may be skipped, and thus not updated, because it always has a zero value.

The multiplication operation of the entries of the DA-F-LUT[n] by μe[n] can be accomplished by using a custom hardware multiplier. However, in one embodiment, the term μe[n] may be quantized to one of L values, each selected to be some power of 2. Thus, the on-chip area usage may be minimized by replacing the custom hardware multiplier by a (less complicated) barrel shifter. In other words, the product of the contents of the DA-A-LUT[n] with μe[n] may be approximated by a right shift of the contents of the DA-A-LUT[n]. While this approximation does not affect the throughput, the approximation may cause a marginal degradation in the convergence of the DAAF 20.

Looking now to FIG. 7, another embodiment of a filter can be implemented using multiple smaller DA Base Filtering and Adaptation units (DA-BFAUs) 82. In comparison to the embodiment of DAAF 20 in FIG. 1, the functions of DA Filter Module 22 and DA Auxiliary Module 24 of FIG. 1 may be viewed as having been combined into the DA-BFAUs 82. Specifically, FIG. 7 depicts the K-tap FIR adaptive filter (DAAF) 80 implemented using m DA-BFAUs 82, each of size k. For simplicity, a k-tap DA-BFAU will be referred as DA-BFAU(k). A K-tap DAAF structure having m DA-BFAU(k), when K=m×k, will be referred as DAAF(k,m). For example, when a 4-tap DA-BFAU is used to implement 128-tap adaptive LMS filter, DAAF structure will be referred as DAAF(4,32).

A single shift register 94 containing the bits of the input samples x[n], x[n−1] . . . , x[n−K+1] may be used, and the k-bit address lines 91, for accessing the contents of the DA-F-LUT 88 of the DA-BFAUs 82 may be derived from this shift register as described in the embodiment of FIG. 3. The throughput, memory requirements, logic complexity and power consumption estimates of the implementation of the system of FIG. 7 will depend in part on the choice of the number m of the DA-BFAUs 82 and their size k.

A DA Filter and Control Module 26′ supplies the control and address signals 92 to each of base units DA-BFAU 82, shift register 94, and accumulator and shift register 86. Thus, all of the base units DA-BFAU 82 may share single DA Filter and Control Module 26′, which supplies the control and address signals 92a. That is, because the structures (including the addresses and control signals) of each of the DA-BFAUs 82 are the same, a single DA Filter Update Control Module 26′ may be used to generate the common addresses and control signals 92a for each DA-BFAU 82. It should be understood that DA Filter Update Control Module 26′ controls the update of each of the lookup tables in each DA-BFAU 82 by providing read and write addresses and control signals, such as write-enable signals, etc. to shift register 94, each DA-BFAU 82, and Accumulator and Shift Register 86 at the appropriate times. However, in the embodiments of FIGS. 7 and 8 the calculations for updating each of the lookup tables take place locally to each DA-BFAU 82, which contains its own filtering and auxiliary tables, as will be described with respect to FIG. 8.

The control line 92b from DA Filter Control Module 26 to shift register 94 may be an enable line. This enable line enables the shift register to shift B times during each sample period, after which the shift register is disabled until the next sample period. The control lines 92c (depicted as a single control line) between the Accumulator and Shift Register 86 are for a sign-bit control signal, an accumulate control signal, and an accumulator reset signal. Once the result y[n] has been obtained, the shifting and accumulating by Accumulator and Shift Register 86 is disabled until the next result is to be calculated. When the next sample period begins, the accumulator may be zeroed out (i.e. reset) by enabling the accumulator reset signal in preparation for the next output sample calculation.

An exemplary DA-BFAU 82 of FIG. 7 is depicted in FIG. 8, and includes a DA-BFAU DA-F-LUT 88 and a DA-BFAU DA-A-LUT 90. DA-BFAU 82 receives address line 91 from shift register 94, which is fed into MUX 95, for determining the read address of the DA-BFAU DA-F-LUT 88. DA-BFAU 82 also receives a signal x_in, which is fed into DA-BFAU 82, for receiving each respective sample x[n], x[n−k], . . . , x[n−(m-1)k] from the previous DA-BFAU 82 x_out signal. Each of the respective samples x[n], x[n−k], . . . , x[n−(m-1)k] received via x_in are stored in register 97 in each respective DA-BFAU 82, used in the update of the DA-A-LUT 90, and passed from the DA-A-LUT 90 via x-out to the next DA-BFAU 82 (the DA-BFAU connected to the output x_out) after the filtering operation for the sample is complete.

In contrast to register 94 (which stores each of the K most recent input samples), register 97 stores the newest input sample for its respective DA-BFAU 82. For example, the embodiment of FIG. 7 is designed such that the first DA-BFAU 82 (receiving sample x[n]) stores the sample x[n], the next DA-BFAU 82 stores sample x[n−k], and so forth. The last (i.e. m^{th}) DA-BFAU 82 stores the sample x[n−(m-1)k]. Accordingly, each of the respective samples (x[n], . . . , x[n−2k]) received are stored in register 97 in each respective DA-BFAU 82, and passed to the next DA-BFAU 82 after the previous signal sample is filtered.

Barrel shifter 96 and adders 98 are present in each of the DA-BFAUs 82 of FIG. 7, and function to update each of the DA-A-LUT 90 and DA-F-LUT 88 (e.g. at steps 58 and 64 of FIG. 4, respectively). Thus, the outputs w_out, of each DA-BFAU 82 may be connected to the adder tree 84 of DAAF 80 (FIG. 7), and the sum 93 output from adder tree 84 is input to the accumulator and shift register 86. Sum 93 is accumulated and shifted B times by accumulator and shift register 86 to generate the output y[n].

In some embodiments the functions of accumulator and shift register 86 may be moved to each DA-BFAU (e.g. before adding each w_out of the DA-BFAU 82). However, this embodiment may add to the footprint of the design. Thus, the embodiment of FIGS. 7 and 8 are depicted as including the accumulator and shift register 86 at the output of the adder tree 84, such that only one shift and accumulator 86 is necessary.

Accordingly, systems and methods for distributed arithmetic adaptive filtering have been disclosed in which all the entries of the filtering lookup table (DA-F-LUT) are updated on a sample-by-sample basis in very few clock cycles. The proposed methodology is not limited to a fixed filter or transform, but will adapt its operation depending on the statistics of the incoming data. Prior adaptive filters have not been implemented using distributed arithmetic because of the difficulty of changing the entire memory contents as the filter weights change. The present invention solves that issue, thereby allowing large adaptive filters to complete their operation in a reasonable number of clock cycles.

It should be emphasized that many variations and modifications may be made to the above-described embodiments. All such modifications and variations are intended to be included herein within the scope of this disclosure and protected by the following claims.

1. A distributed arithmetic adaptive filter comprising:
a plurality of registers, each register storing one of K incoming signal samples;
a memory for storing a first and second lookup table, the first lookup table including 2^{K} filter weight sums, each of the 2^{K} filter weight sums addressed by at least one bit of each of the K signal samples stored in the plurality of registers; and
a controller configured to:
update the second lookup table with each possible combination of the sums of the K most recent input samples; and
update each of the 2^{K} filter weight sums of the first lookup table based on the combination of the sums of the K most recent input samples stored in the second lookup table.

2. The adaptive filter of claim 1, wherein the adaptive filter is configured to filter the incoming signal sample with one of the 2^{K} filter weight sums in the first lookup table while the controller updates the second lookup table with each possible combination of the sums of the K most recent input samples.

3. The adaptive filter of claim 2, wherein the controller is further configured to update each of the 2^{K} filter weight sums of the first lookup table before a subsequent incoming signal sample is filtered.

4. The adaptive filter of claim 1, wherein the second lookup table contains all possible combination sums of the K input samples at time n−1, each combination sum mapped to an addressed location; and wherein the controller is further configured to update the second lookup table to contain all possible combination sums of the K input samples at time n by:
remapping the combination sums of the input samples stored within a first half of the second lookup table to each of the even addressed locations of the second lookup table; and
for each of the odd addressed locations of the second lookup table:
reading the combination sum from the preceding even addressed location of the second lookup table;
adding the latest of the K incoming signal samples to the combination sum read from the preceding even addressed location to determine an updated combination sum; and
storing the updated combination sum into the odd addressed location.

5. The adaptive filter of claim 4, wherein the controller is further configured to
update each of the 2^{K} filter weight sums of the first lookup table by iteratively updating each addressed location of the first lookup table with an updated filter weight sum, the iterative update of each addressed location including:
adding the filter weight sum value of the addressed location of the first lookup table to a product of a step size, a calculated error, and the updated combination sum located in the corresponding addressed location of the second lookup table; and
storing the updated filter weight sum into the addressed location.

6. The adaptive filter of claim 4, wherein the controller is further configured to
map the contents of a first half of the second lookup table to each of the even addressed locations of the second lookup table by rotating the address lines that externally access the second lookup table.

7. The adaptive filter of claim 1, wherein the second lookup table contains each possible combination of the sums of the most recent input samples.

8. The adaptive filter of claim 1, wherein the 2^{k} filter weight sums stored in the first lookup table comprise each possible filter weight combination sum.

9. The adaptive filter of claim 1, wherein the plurality of registers store the K most recent incoming input signal samples.

10. The adaptive filter of claim 1, wherein the at least one bit of each of the K signal samples is a consecutive bit of each of the K signal samples.

11. The adaptive filter of claim 10, wherein the consecutive bit is the rightmost bit of each of the K signal samples.

12. A method for adaptive filtering comprising:
filtering a signal with at least one of a plurality of filter weight sums stored in a first lookup table, each of the filter weight sums addressed by at least one bit of each of a plurality of received input samples; and
updating content in a second lookup table during the step of filtering the signal, the second look-up table contents including sums of the plurality of input samples.

13. The method of claim 12, wherein the step of updating content in a second lookup table includes rotating address lines of the second lookup table.

14. The method of claim 13, wherein the step of rotating address lines remaps the sums of the plurality of input samples stored within a first half of the second lookup table to even addressed locations of the second lookup table.

15. The method of claim 14, wherein the step of updating content in the second lookup table further comprises, for each of the odd addressed locations of the second lookup table:
reading the sum from the preceding even addressed location of the second lookup table;
adding the latest of the incoming signal samples to the sum read from the preceding even addressed location to determine an updated sum; and
storing the updated sum into the odd addressed location.

16. The method of claim 12, further including:
updating the content of the first lookup table based on the combination of the sums of the K input samples stored in the second lookup table.

17. The method of claim 16, further including:
storing the updated content in each of the odd addressed locations of the second lookup table.

18. The method of claim 12, further including:
calculating an updated content of each of the odd addressed locations of the second lookup table by iteratively adding the most recent input sample to the contents of each previous evenly addressed location in the second lookup table.

19. The method of claim 12, wherein the at least one bit of each of the plurality of received input samples is a corresponding consecutive bit of each of the plurality of received input samples.

20. The method of claim 19, wherein the corresponding consecutive bit of each of the plurality of received input samples is the rightmost bit of each of the plurality of received input samples.

21. The method of claim 12, wherein the plurality of filter weight sums stored in the first lookup table comprise each possible combination sum of the filter weights.

22. The method of claim 12, wherein the sums of the plurality of input samples of the second lookup table comprise each possible combination of the sums of the most recent input samples.

23. A digital adaptive filter comprising:
at least one register for storing K input samples; and
at least one sub-filter, each sub-filter accessing a first and second lookup table, the first lookup table including a plurality of filter weight sums, the plurality of filter weight sums addressed by at least one bit of each of the signal samples stored in the at least one register, the second lookup table including a plurality of values dynamically updated based on the sums of the K input samples.

24. The adaptive filter of claim 23, wherein the adaptive filter comprises m sub-filters having k inputs, each of the sub-filters configured to:
update the second lookup table during filtration of a first input sample; and
update each of the filter weight sums of the first lookup table based on the values stored in the second lookup table after filtering the first input sample.

25. The adaptive filter of claim 23, further comprising:
an adder tree in electrical communication with an output of each of the at least one sub-filters, the adder tree configured to sum the outputs of each of the sub-filters.

26. The adaptive filter of claim 25, further comprising:
means for accumulating and shifting configured to receive the sum of the outputs of each of the sub-filters from the adder tree and generate a filtered signal.

27. The adaptive filter of claim 23, wherein the at least one bit of each of the signal samples is a corresponding consecutive bit of each of the signal samples.

28. The adaptive filter of claim 23, wherein the corresponding consecutive bit of each of the signal samples is the rightmost bit of each of the signal samples.

29. The adaptive filter of claim 23, wherein the plurality of filter weight sums in the first lookup table comprise each possible combination sum of filter weights.

30. The adaptive filter of claim 23, wherein the values of the second lookup table include each possible combination of the sums of the most recent input samples.

31. The adaptive filter of claim 23, further comprising:
a controller in electrical communication with each of the at least one sub-filters, the controller providing common addresses and control signals for each sub-filter.

32. A method for adaptive filtering comprising:
filtering a signal with a plurality of sub-filters, each sub-filter accessing a first and second lookup table, the first lookup table including a plurality of filter weight sums, the plurality of filter weight sums addressed by at least one bit of each of the signal samples stored in the at least one register, the second lookup table including a plurality of values dynamically updated based on the sums of K input samples.

33. The adaptive filtering method of claim 32, further including:
updating the second lookup table in each of the sub-filters during filtration of a first input sample; and
update each of the filter weight sums of the first lookup table in each of the sub-filters based on the values stored in the second lookup table after filtering the first input sample.

34. The adaptive filtering method of claim 32, further including summing the outputs of each of the sub-filters.

35. The adaptive filtering method of claim 34, further including
generating a filtered signal by accumulating and shifting the sum of the outputs of each of the sub-filters.

36. The adaptive filtering method of claim 33, further comprising:
controlling each of the at least one sub-filters by providing common addresses and control signals for each sub-filter.

37. The adaptive filtering method of claim 33, wherein the plurality of filter weight sums in the first lookup table comprise each possible combination sum of filter weights.

38. The adaptive filtering method of claim 33, wherein the values of the second lookup table include each possible combination of the sums of the most recent input samples.
